(19) United States
(12) Patent Application Publication
(10) Pub. No.: US 2026/0282479 A1
(43) Pub. Date: Sep. 17, 2026

(54) SEMICONDUCTOR SUBSTRATE, AND METHOD FOR MANUFACTURING SEMICONDUCTOR SUBSTRATE

(71) Applicant: KYOCERA CORPORATION, Kyoto-shi, Kyoto (JP)

(72) Inventors: Takeshi KAMIKAWA, Kyoto-shi (JP); Noboru SUDA, Kyoto-shi (JP); Fumio YAMASHITA, Kyoto-shi (JP); Yuta AOKI, Kyoto-shi (JP); Mitsunari SEIDA, Kyoto-shi (JP)

(73) Assignee: KYOCERA CORPORATION, Kyoto-shi, Kyoto (JP)

(21) Appl. No.: 19/469,210

(22) PCT Filed: Mar. 27, 2024
(86) PCT No.: PCT/JP2024/012324

§ 371 Date: Sep. 25, 2025

(30) Foreign Application Priority Data
Mar. 27, 2023 (WO) PCT/JP2023/012079

(51) Int. Cl. H10D 62/85; H10P 14/20

(52) U.S. Cl. CPC H10D 62/8503; H10P 14/276; H10P 14/3416

(57) ABSTRACT

A semiconductor substrate includes: a main substrate; a seed pattern that is located above the main substrate and includes a first region; and a first semiconductor part extending from the first region, wherein the main substrate is a substrate made of a bulk crystal that is not a nitride semiconductor, and part of a surface of the main substrate is a non-seed region that does not overlap the seed pattern in plan view.

### TECHNICAL FIELD

The present disclosure relates to a semiconductor substrate and the like.

### BACKGROUND OF INVENTION

A mask pattern in which a nitride semiconductor layer does not grow is formed on a base substrate including a heterogeneous substrate and a seed layer, and the nitride semiconductor layer is laterally grown on a mask portion by using, as a growth starting point, the seed layer exposed in an opening portion where the mask portion is not provided. Thereby, the defect density of the nitride semiconductor layer on the mask portion can be reduced (Patent Document 1).

### CITATION LIST

### Patent Literature

Patent Document 1: JP 2013-251304 A

### SUMMARY

A semiconductor substrate according to the present disclosure includes a main substrate, a seed pattern that is located above the main substrate and includes a first region, and a first semiconductor part extending from the first region, wherein the main substrate is a substrate made of a bulk crystal that is not a nitride semiconductor, and part of a surface of the main substrate is a non-seed region that does not overlap the seed pattern in plan view.

### BRIEF DESCRIPTION OF THE DRAWINGS

FIG. 1 is a plan view illustrating a configuration of a template substrate according to the present embodiment.

FIG. 2 is a cross-sectional view illustrating a configuration of the template substrate according to the present embodiment.

FIG. 3 is a flowchart illustrating a method for manufacturing the template substrate according to the present embodiment.

FIG. 4 is a block diagram illustrating a manufacturing apparatus for the template substrate according to the present embodiment.

FIG. 5 is a flowchart illustrating a method for manufacturing the template substrate.

FIG. 6 is cross-sectional views each illustrating a method for manufacturing the template substrate.

FIG. 7 is cross-sectional views each illustrating a method for manufacturing the template substrate.

FIG. 8 is cross-sectional views each illustrating a method for manufacturing the template substrate.

FIG. 9 is a cross-sectional view illustrating a configuration of the template substrate according to the present embodiment.

FIG. 10 is a cross-sectional view illustrating a configuration of the template substrate according to the present embodiment.

FIG. 11 is a cross-sectional view illustrating a configuration of the template substrate according to the present embodiment.

FIG. 12 is a cross-sectional view illustrating a configuration of the template substrate according to the present embodiment.

FIG. 13 is cross-sectional views each illustrating a method for manufacturing the template substrate.

FIG. 14 is cross-sectional views each illustrating a method for manufacturing the template substrate.

FIG. 15 is a plan view illustrating a configuration of a semiconductor substrate according to the present embodiment.

FIG. 16 is a cross-sectional view illustrating the configuration of the semiconductor substrate according to the present embodiment.

FIG. 17 is a plan view illustrating a configuration of a semiconductor substrate according to the present embodiment.

FIG. 18 is a cross-sectional view illustrating the configuration of the semiconductor substrate according to the present embodiment.

FIG. 19 is a flowchart illustrating a method for manufacturing a semiconductor substrate according to the present embodiment.

FIG. 20 is a block diagram illustrating the manufacturing apparatus for a semiconductor substrate according to the present embodiment.

FIG. 21 is a flowchart illustrating a manufacturing method for a semiconductor substrate according to the present embodiment.

FIG. 22 is cross-sectional views each illustrating the manufacturing method for a semiconductor substrate according to the present embodiment.

FIG. 23 is a cross-sectional view illustrating the configuration of the semiconductor substrate according to the present embodiment.

FIG. 24 is a cross-sectional view illustrating the configuration of the semiconductor substrate according to the present embodiment.

FIG. 25 is a cross-sectional view illustrating the configuration of the semiconductor substrate according to the present embodiment.

FIG. 26 is plan views each illustrating the method for manufacturing the semiconductor substrate according to the present embodiment.

FIG. 27 is plan views each illustrating the manufacturing method for a semiconductor substrate and a semiconductor device according to the present embodiment.

FIG. 28 is a plan view illustrating the manufacturing method for a semiconductor substrate and a semiconductor device according to the present embodiment.

FIG. 29 is cross-sectional views each illustrating the manufacturing method for a semiconductor substrate and a semiconductor device according to the present embodiment.

FIG. 30 is cross-sectional views each illustrating the manufacturing method for a semiconductor substrate according to the present embodiment.

FIG. 31 is cross-sectional views each illustrating the manufacturing method for a semiconductor substrate according to the present embodiment.

FIG. 32 is cross-sectional views each illustrating the manufacturing method for a semiconductor substrate according to the present embodiment.

FIG. 33 is a cross-sectional view illustrating a configuration example of an electronic device according to the present embodiment.

FIG. 34 is a cross-sectional view illustrating a configuration example of an electronic device according to the present embodiment.

### DESCRIPTION OF EMBODIMENTS

### Semiconductor Growth Template Substrate

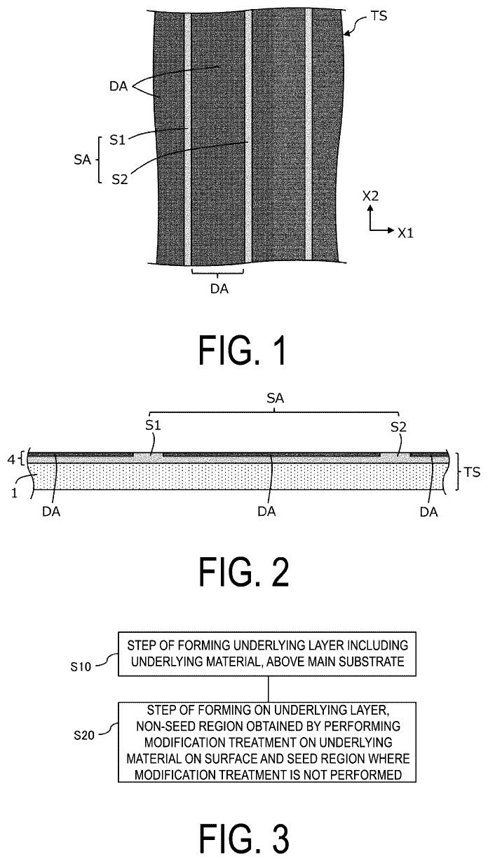

A semiconductor growth template substrate according to the present embodiment will be described. Hereinafter, the semiconductor growth template substrate is simply referred to as a template substrate. FIG. 1 is a plan view illustrating a configuration of a template substrate according to the present embodiment. FIG. 2 is a cross-sectional view illustrating a configuration of the template substrate according to the present embodiment. As illustrated in FIGS. 1 and 2, a template substrate TS includes a main substrate 1 and an underlying layer 4 that is located above the main substrate 1 and includes an underlying material, and the underlying layer 4 has a surface including a growth suppression region DA in which the underlying material is modified and a seed region (seed pattern) SA in which the underlying material is not modified. The modification (surface modification) may be about changing at least one of the contained element and the crystal structure of the surface of the underlying layer, and at least one of the contained element and the crystal structure may be different between the growth suppression region DA and the seed region SA. The growth suppression region DA may be a selective growth region (non-seed region). The growth suppression region DA may be polycrystalline or amorphous. The growth suppression region DA may have a larger occupancy ratio of amorphous or polycrystalline than the seed region SA.

The growth suppression region DA may have a higher impurity concentration than the seed region SA, and the impurity concentration may be an oxygen concentration or an argon concentration. At least one element of oxygen (O), silicon (Si), and carbon (C), which is taken into the vicinity of a surface of the growth suppression region DA (for example, a depth of about 0 to 5 nm) in the process of forming the growth suppression region DA, may enhance the growth suppression function.

Since the template substrate according to the present embodiment does not include a known mask pattern, lateral growth (ELO) of a semiconductor part (for example, nitride semiconductor crystal) from the seed region SA (non-modified region of the surface of the underlying layer 4) to a portion above the growth suppression region DA (modified region of the surface of the underlying layer 4) is facilitated, whereby the semiconductor part (semiconductor layer) with a high quality can be obtained. Depending on a film formation condition of the lateral growth, it is possible to suppress a phenomenon in which impurities liberated from the mask pattern are taken into the semiconductor part during the growth. When the impurities are excessively taken into the semiconductor part during the growth, the impurities are segregated on the surface of the laterally grown semiconductor part, and this may lead to problems such as difficulty in forming the upper layer film on the laterally grown semiconductor part and occurrence of defects from the interface with the upper layer film. If the film formation condition for the lateral growth is limited in order to avoid these problems, it may be difficult to form a film of a semiconductor part having a large aspect ratio (ratio of the lateral width to the film thickness), meaning that the degree of freedom of the shape of the semiconductor part for device design is compromised.

In the present embodiment, no mask pattern is formed, and the material debris generated from the growth suppression region is reduced by modifying the underlying layer 4, whereby the laterally grown semiconductor part (for example, a nitride semiconductor crystal) with a high quality can be obtained. The aspect ratio of the semiconductor part may be, for example, 5.0 or more, 10.0 or more, or 20.0 or more.

As illustrated in FIG. 1, the seed region SA may include a first region (first growth initiation region) S1 and a second region (second growth initiation region) S2, and the growth suppression region DA may be located between the first region S1 and the second region S2. The first region S1 and the second region S2 may be arranged in a stripe pattern.

The underlying material that is the main constituent of the underlying layer 4 may be a nitride semiconductor, and the main substrate 1 may be a heterogeneous substrate having a lattice constant different from that of the nitride semiconductor. The growth suppression region DA and the seed region SA may be arranged in an a-axis direction of the nitride semiconductor. The width (the length in the a-axis direction) of the growth suppression region DA may be five times the width (the length in the a-axis direction) of the first region S1 or more.

The nitride semiconductor may be expressed by, for example, AlxGayInzN (0≤x≤1;0≤y≤1;0≤z≤1;x+y+z=1). Specific examples of the nitride semiconductor include a GaN-based semiconductor, aluminum nitride (AlN), indium aluminum nitride (InAlN), and indium nitride (InN). The GaN-based semiconductor is a semiconductor containing gallium atoms (Ga) and nitrogen atoms (N). Typical examples of the GaN-based semiconductor include GaN, AlGaN, AlGaInN, and InGaN.

The underlying material may be, for example, aluminum nitride, and an aluminum layer (Al layer) may be provided between the main substrate 1 and the underlying layer 4 which is an AlN layer. The heterogeneous substrate includes a silicon substrate, a silicon carbide substrate, a sapphire substrate, an aluminum nitride substrate, and a ScAlMgO₄ substrate, and the like.

The underlying material may contain different materials (for example, a metal element other than a group III metal element) such as scandium (Sc), Zn, and Cr, and the underlying material may be AlScN, ScN, ZnO, CrN, and the like. The underlying layer 4 may have a single-layer structure or a multi-layer structure. The multi-layer structure may include a periodic structure.

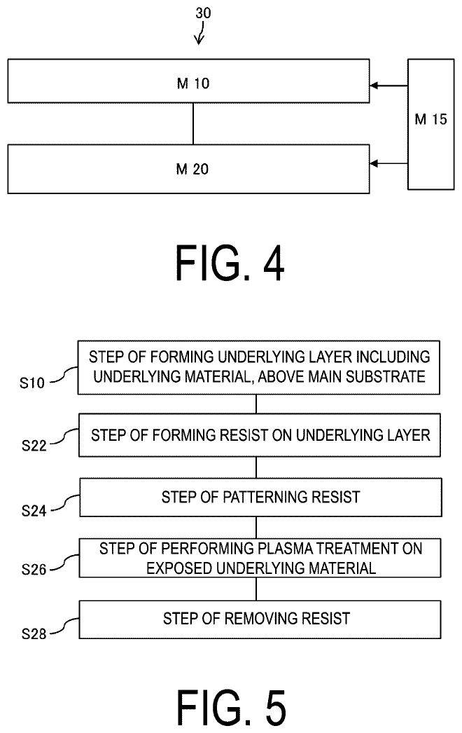

FIG. 3 is a flowchart illustrating a method for manufacturing the template substrate according to the present embodiment. As illustrated in FIG. 3, the method for manufacturing a template substrate according to the present embodiment includes step S10 of forming the underlying layer 4, including an underlying material (for example, aluminum nitride), above the main substrate 1 (for example, a silicon substrate), and step S20 of forming on the underlying layer 4, the growth suppression region DA obtained by performing a modification treatment on the underlying material on the surface and the seed region SA not subjected to the modification treatment. FIG. 4 is a block diagram illustrating a manufacturing apparatus for the template substrate according to the present embodiment. A manufacturing apparatus 30 for a template substrate includes an apparatus M10 that performs step S10 in FIG. 3, an apparatus M20 that performs the step S20 in FIG. 3, and a control device M15 that controls the apparatus M10 and the apparatus M20. The apparatus M20 may be an apparatus that performs the modification treatment.

FIG. 5 is a flowchart illustrating a method for manufacturing the template substrate.

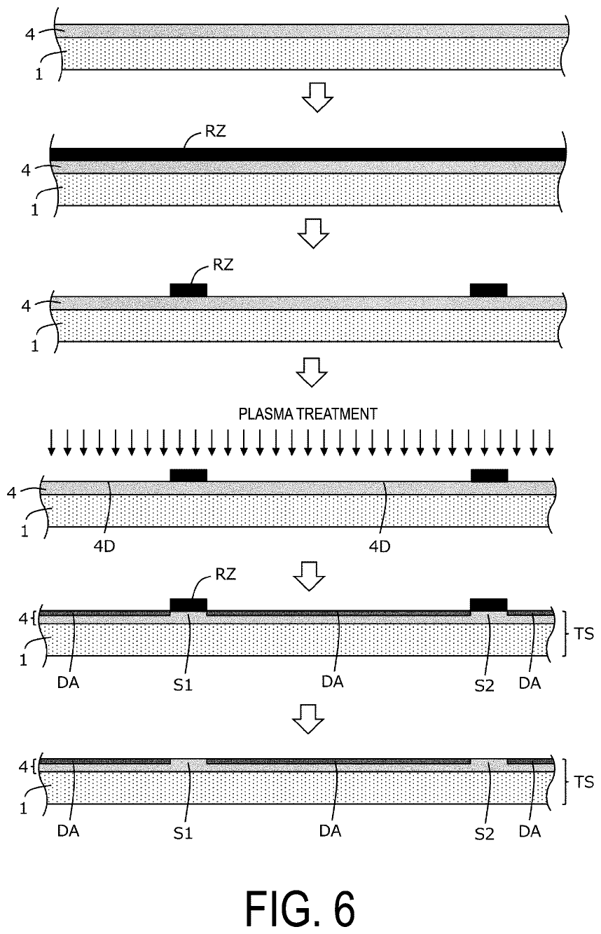

FIG. 6 is cross-sectional views each illustrating a method of manufacturing the template substrate. As illustrated in FIGS. 5 and 6, as step S20 after step S10 of forming the underlying layer 4 including the underlying material, step S22 of forming a resist RZ by film formation on the underlying layer 4, step S24 of patterning the resist RZ, step S26 of subjecting the exposed underlying material to a plasma treatment, and step S28 of removing the resist RZ may be performed. The underlying layer 4 may be formed by a sputtering method.

For example, in the plasma treatment, an exposed surface 4D of the underlying layer 4 is irradiated with an argon plasma to modify the surface of the irradiated regions, and form the growth suppression region DA. By introducing not only argon gas, but also oxygen gas, nitrogen gas, hydrogen gas or the like into the chamber, an oxygen plasma, a nitrogen plasma, a hydrogen plasma, or a mixed plasma of these plasma types can be used in the plasma treatment, in addition to the argon plasma. Thus, the growth suppression region DA may contain argon, oxygen, nitrogen, or the like as an impurity. In such a case, the underlying material may be aluminum nitride and the growth suppression region DA may include aluminum oxynitride. The underlying material may be aluminum scandium nitride (AlScN) and the growth suppression region DA may include aluminum scandium oxynitride (AlScON).

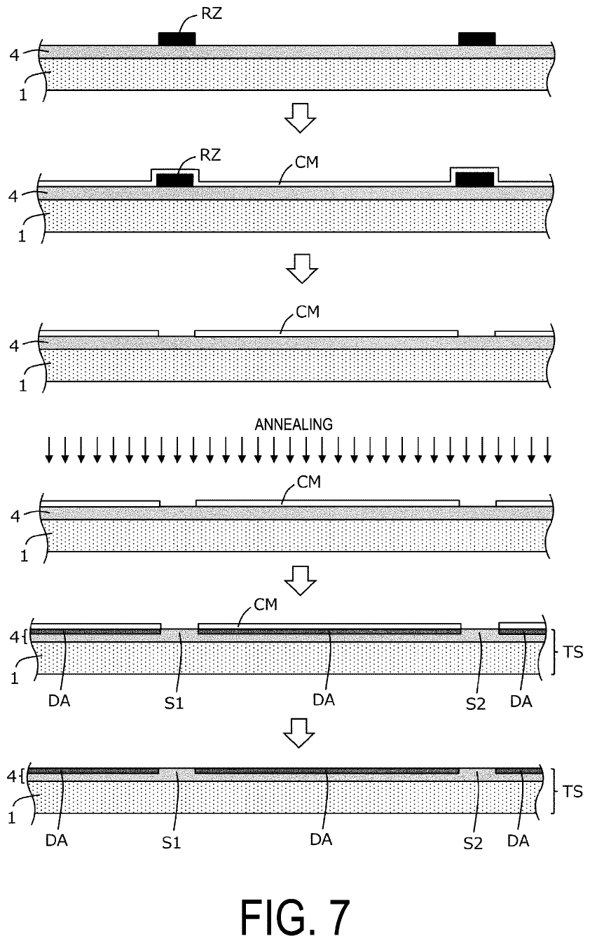

FIG. 7 is cross-sectional views illustrating a method of manufacturing a template substrate. As illustrated in FIG. 7, the following steps may be performed: a step of forming the resist RZ by patterning on the underlying layer 4 (for example, an AlN layer), a step of forming a coating film CM (for example, a silicon nitride film of about 10 nm) covering the underlying layer 4 and the resist RZ, a step of removing the resist RZ (lift-off patterning of the coating film CM), a step of annealing the coating film CM and the underlying layer 4 (for example, by a thermal treatment at 1000° C.), and a step of removing the coating film CM (for example, removing the silicon nitride film with buffered HF (BHF)). Thus, the growth suppression region DA located under the coating film CM can be formed on the surface of the underlying layer 4 by a mutual diffusion phenomenon between the underlying layer 4 and the coating film CM during annealing. By forming the coating film CM by sputtering, the surface under the coating film CM can be modified, without implementing the annealing treatment. The underlying material may contain different materials (for example, a metal element other than a group III metal element) such as scandium (Sc), Zn, and Cr, and the underlying material may be AlScN, ScN, ZnO, CrN, and the like. The underlying layer 4 may have a single-layer structure or a multi-layer structure. The multi-layer structure may include a periodic structure.

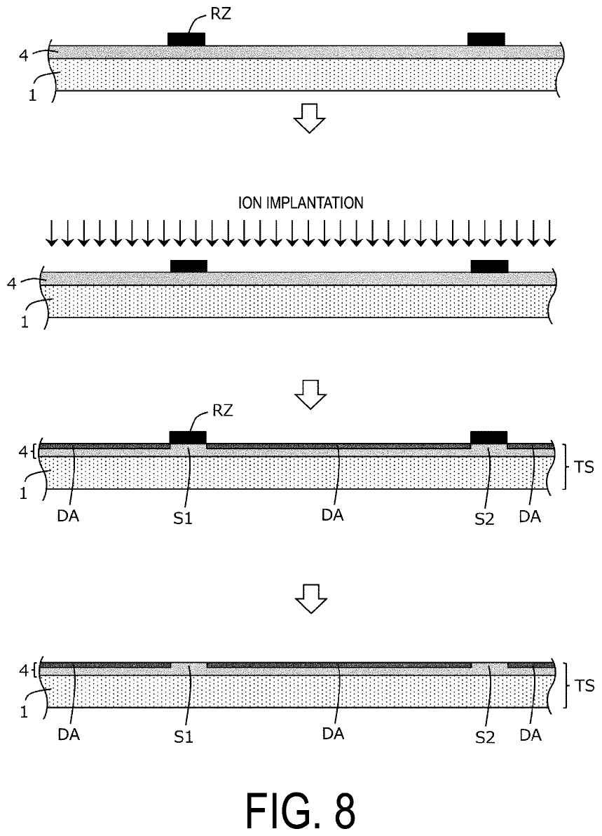

FIG. 8 is cross-sectional views each illustrating a method of manufacturing a template substrate. As illustrated in FIG. 8, a step of forming the resist RZ by patterning on the underlying layer 4 (for example, an AlN layer), a step of subjecting the exposed underlying material to an impurity ion implantation treatment, and a step of removing the resist RZ may be performed. Examples of the impurities include silicon (Si), iron (Fe), magnesium (Mg), and the like. In the implantation treatment, impurity ions are implanted into the exposed surface 4D of the underlying layer 4 to modify the surface, and thus, the growth suppression region DA is formed. The underlying material may contain different materials (for example, a metal element other than a group III metal element) such as scandium (Sc), Zn, and Cr, and the underlying material may be AlScN, ScN, ZnO, CrN, and the like. The underlying layer 4 may have a single-layer structure or a multi-layer structure. The multi-layer structure may include a periodic structure.

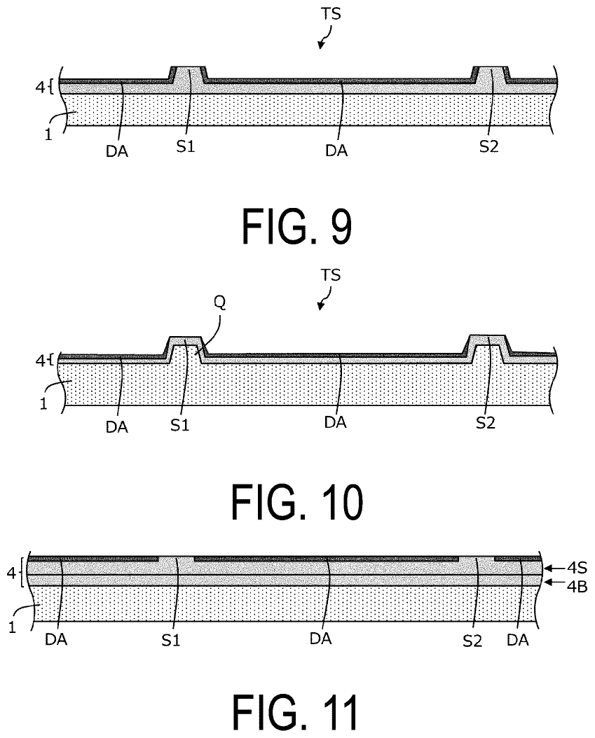

FIG. 9 and FIG. 10 are cross-sectional views illustrating a configuration of the template substrate according to the present embodiment. As illustrated in FIG. 2, the growth suppression region DA and the seed region SA may be flush with each other, or as illustrated in FIGS. 9 and 10, the seed region SA (the first and the second regions S1 and S2) may be located more on the upper side than the growth suppression region DA (planar region). This facilitates the lateral growth of the semiconductor from the seed region SA to the growth suppression region DA, compared with the known case where the seed surface is located below the upper surface of the mask pattern. For example, as illustrated in FIG. 9, the underlying layer 4 may have a configuration in which a portion including the first region S1 is thicker than a portion including the growth suppression region DA, that is, a configuration in which a portion immediately below the first region S1 (a portion overlapping the first region S1 in plan view) is thicker than a portion immediately below the growth suppression region DA (a portion overlapping the growth suppression region DA in plan view). As illustrated in FIG. 10, the main substrate 1 may include a protruding portion Q projecting upward, and the first region S1 may be located on the protruding portion Q.

The underlying material may contain different materials (for example, a metal element other than a group III metal element) such as scandium (Sc), Zn, and Cr, and the underlying material may be AlScN, ScN, ZnO, CrN, and the like. The underlying layer 4 may have a single-layer structure or a multi-layer structure. The multi-layer structure may include a periodic structure.

The growth suppression region DA formed by the surface modification process may have a thickness (t) satisfying 0<thickness (t)≤100 nm or 0<thickness (t)≤20 nm. In this case, the surface (lower surface) closer to main substrate 1 may have a higher impurity concentration than the surface (upper surface) farther from main substrate 1.

FIG. 11 is a cross-sectional view illustrating a configuration of the template substrate according to the present embodiment. As illustrated in FIG. 11, the underlying layer 4 may include a buffer layer 4B located on the main substrate 1 side and a seed layer 4S located on the surface side. For example, a silicon substrate may be used as the main substrate 1, an Al layer may be used as the buffer layer 4B, and an AlN layer may be used as the seed layer 4S. A silicon substrate may be used as the main substrate 1, an AlN layer may be used as the buffer layer 4B, and a GaN-based semiconductor layer may be used as the seed layer 4S.

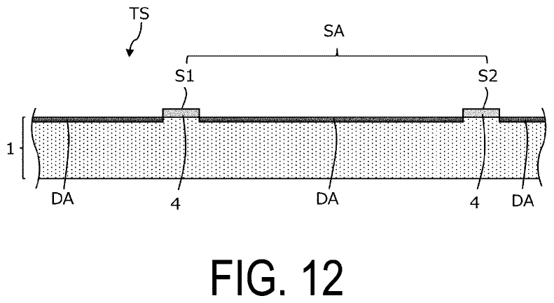

FIG. 12 is a cross-sectional view illustrating a configuration of the template substrate according to the present embodiment. As illustrated in FIG. 12, the template substrate TS includes the main substrate 1 and the underlying layer 4 located on the main substrate 1, and includes the seed region SA located on the surface of the underlying layer and the growth suppression region DA that is located on the surface of the main substrate and is formed by modifying the main substrate material. The main substrate 1 may be a silicon substrate or a silicon carbide substrate. The growth suppression region may include a silicon thermal oxide film. The main substrate 1 may be an AlN substrate or a sapphire substrate.

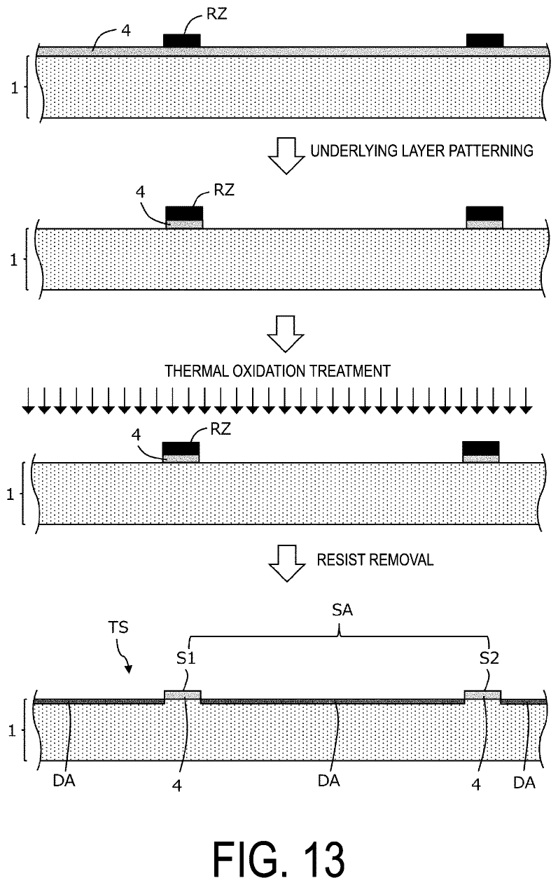

FIG. 13 is cross-sectional views each illustrating a method of manufacturing a template substrate. As illustrated in FIG. 13, step of patterning and forming the underlying layer 4 (for example, an AlN layer) on the main substrate 1 (for example, a silicon substrate or a silicon carbide substrate) using, for example, the resist RZ, and step of performing a thermal oxidation treatment on the exposed main substrate surface may be performed. The underlying layer 4 may be covered with the resist RZ during the thermal oxidation treatment. In the thermal oxidation treatment, the exposed surface of the main substrate 1 is modified (oxidized) to form a thermal oxide film, thereby forming the growth suppression region DA. The growth suppression region DA may be formed by performing a nitriding treatment instead of the thermal oxidation treatment.

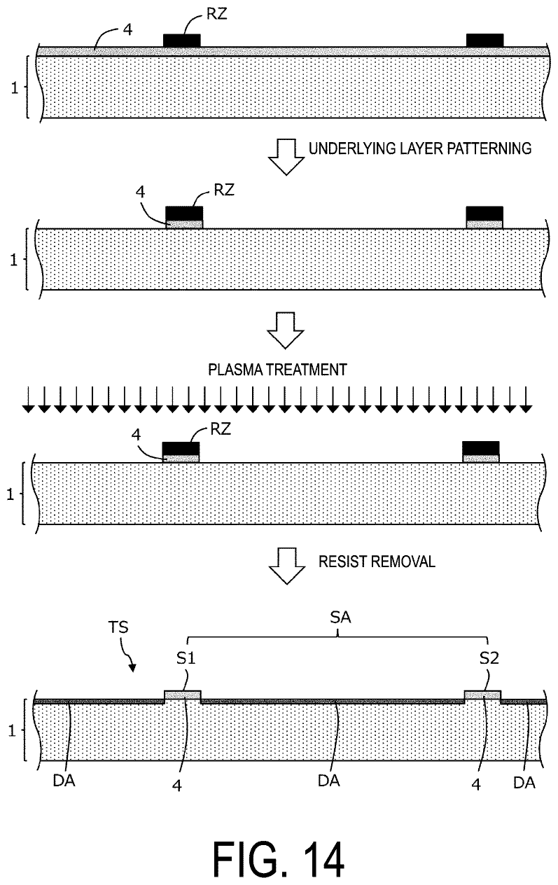

FIG. 14 is cross-sectional views each illustrating a method of manufacturing a template substrate. As illustrated in FIG. 14, step of patterning and forming the underlying layer 4 (for example, an AlN layer or a GaN-based semiconductor layer) on the main substrate 1 (for example, a silicon carbide substrate, a sapphire substrate, or an AlN substrate) and step of performing a plasma treatment on the exposed main substrate surface may be performed. In the plasma treatment, the exposed surface of the main substrate 1 is modified to form the growth suppression region DA. The growth suppression region DA may be formed by performing an impurity ion implantation process instead of the plasma treatment.

### Semiconductor Substrate

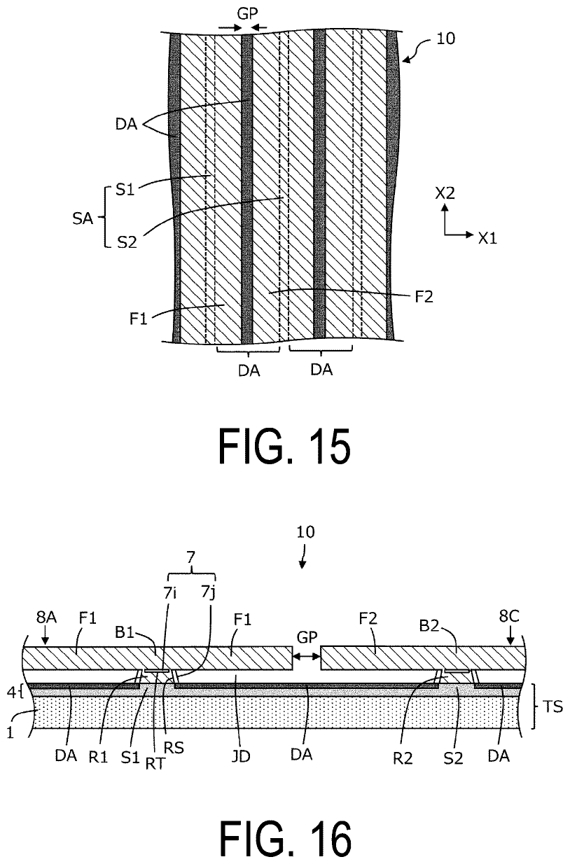

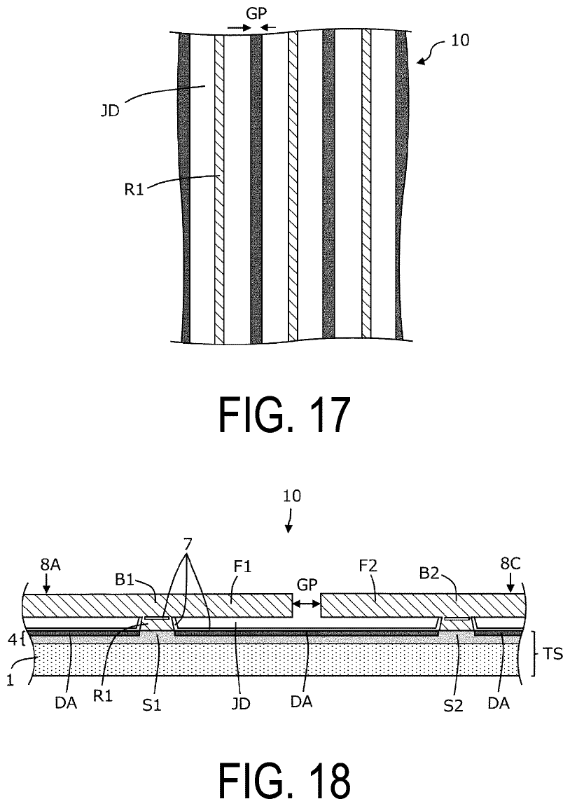

FIG. 15 is a plan view illustrating a configuration of a semiconductor substrate according to the present embodiment. FIG. 16 is a cross-sectional view illustrating the configuration of the semiconductor substrate according to the present embodiment. FIG. 17 is a plan view illustrating a configuration of a semiconductor substrate according to the present embodiment. As illustrated in FIGS. 15 to 17, a semiconductor substrate 10 includes the template substrate TS including the growth suppression region DA and the seed region SA (including the first and the second regions S1 and S2) arranged in a first direction X1, and the first semiconductor part 8A that is located above the template substrate TS and includes a nitride semiconductor. The first semiconductor part 8A includes a first raised portion R1 reaching a position more on the upper side than the growth suppression region DA (planar region) from the first region S1, a first base portion B1 located above the first raised portion R1, and a first wing portion F1 that is connected to the first base portion B1, separated from the growth suppression region DA, and located above the void space JD. The semiconductor substrate 10 may include a growth suppression film 7 in contact with the first raised portion R1.

The template substrate TS includes the main substrate 1 and the underlying layer 4 located on the main substrate 1. The underlying layer 4 may be made of a nitride semiconductor containing 2*1018/cm³ or more of argon or oxygen as impurities. For example, the underlying layer 4 can be formed by a sputtering method using argon gas. A direction from the main substrate 1 to the first semiconductor part 8A is referred to as an “upward direction”. Viewing an object with a line of sight parallel to a normal direction of the semiconductor substrate 10 (including viewing an object in a perspective manner) may be referred to as a “plan view”.

The first region S1, the first raised portion R1, and the first base portion B1 may overlap in plan view, and the growth suppression region DA and the first wing portion F1 may overlap in plan view. The first wing portion F1 may not be in contact with the side surface of the first raised portion R1.

The first semiconductor part 8A contains a nitride semiconductor as a main constituent. The first semiconductor part 8A may be a doped type semiconductor (for example, an n-type semiconductor including a donor) or a non-doped type semiconductor. The semiconductor substrate refers to a substrate containing a semiconductor. The main substrate 1 of the template substrate TS may contain a semiconductor (for example, silicon or silicon carbide), or may not contain a semiconductor.

The first direction X1 may be an a-axis direction (<11-20> direction) of the first semiconductor part 8A. A second direction X2 may be an m-axis direction (<1-100> direction) of the first semiconductor part 8A (a nitride semiconductor such as a GaN semiconductor). A thickness direction of the first semiconductor part 8A may be a c-axis direction (<0001> direction) of the first semiconductor part 8A. The first semiconductor part 8A may include a pair of two first wing portions F1 extending from the first base portion B1 in the first direction X1 and in a direction opposite to the first direction X1.

The first semiconductor part 8A can be formed by an Epitaxial Lateral Overgrowth (ELO) method with the first raised portion R1 growing from the first region S1 serving as a starting point. Among the first semiconductor part 8A, the base portion B1 located above the first region S1 serves as a dislocation succession portion in which a large number of threading dislocations occur. The first wing portion F1 located above the growth suppression region DA serves as a low defect portion having a low threading dislocation density compared with the dislocation succession portion.

Thus, by forming the first raised portion R1 and forming the first wing portion F1 that extends in a lateral direction (a direction parallel to the first direction X1) from the first base portion B1 on the first raised portion R1, is separated from the growth suppression region DA and is located above the void space JD, the first wing portion F1 having a large width, low defect density, and high flatness can be formed. The entire first wing portion F1 may be spaced apart from the growth suppression region DA. Thus, the first wing portion F1 having a large width, low defect density, and high flatness can be formed. When the first wing portion F1 is laterally grown (by ELO) to be spaced apart from the growth suppression region DA, the conditions required for the growth suppression region DA are small. There is also an advantage that conditions such as the shape of the growth suppression region DA, the selective growth function, the adhesion with the semiconductor part 8, and the stress characteristics are relaxed, and a high degree of freedom is achieved for the growth suppression region DA.

The semiconductor substrate 10 may include a second semiconductor part 8C located above the template substrate TS. The template substrate TS may include the second region S2 adjacent to the first region S1 via the growth suppression region DA. The second semiconductor part 8C may include a second raised portion R2 reaching a position more on the upper side than the growth suppression region DA (planar region) from the second region S2, a second base portion B2 located above the second raised portion R2, and a second wing portion F2 that is connected to the second base portion B2, separated from the growth suppression region DA, and located above the void space JD. The first wing portion F1 and the second wing portion F2 may be aligned in the first direction X1 with a gap GP therebetween.

In the following description, the first raised portion R1 and the second raised portion R2 may be collectively referred to as a raised portion R, the first semiconductor part 8A and the second semiconductor part 8C may be collectively referred to as a semiconductor part 8, the first wing portion F1 and the second wing portion F2 may be collectively referred to as a wing portion F, and the first base portion B1 and the second base portion B2 may be collectively referred to as a base portion B.

The growth suppression film 7 may be in contact with a side surface RS of the first raised portion R1. Thus, the growth of the semiconductor part 8 from the side surface RS is suppressed, so that the void space JD is easily formed. In order to achieve the effect of the present embodiment, the growth suppression film 7 may be formed on at least a part of the side surface RS of the first raised portion R1, and may include a first film portion 7j in contact with the side surface RS of the first raised portion R1 and a second film portion 7i in contact with an upper surface RT of the first raised portion R1. The growth suppression film 7 may not completely be formed as a film, and may be a film including one or more small openings (a film having an incomplete shape). By forming the second film portion 7i, a new effect can be obtained by which the threading dislocation or the like that propagates from the seed part 3 to the first raised portion R1 is suppressed by the second film portion 7i and the surface flatness and the crystallinity of the first base portion B1.

The side surface RS of the first raised portion R1 may be a tapered surface having a shape that is narrow upward. Thus, the width of the void space JD facing the back surface of the first wing portion F1 can be made wider than the width of the void space JD facing the growth suppression region DA, so that the first wing portion F1 having less defects can be formed wider.

The side surface RS, which is a tapered surface, may intersect the growth suppression region DA. The growth suppression film 7 may be in contact with the upper surface RT of the first raised portion R1. Among the growth suppression film 7 in contact with the first raised portion R1, the second film portion 7i located on the upper surface RT of the first raised portion R1 (a portion in contact with the upper surface RT of the first raised portion R1) may be included in the first semiconductor part 8A. Therefore, the stress from the template substrate TS is relaxed.

FIG. 18 is a cross-sectional view illustrating the configuration of the semiconductor substrate according to the present embodiment. As illustrated in FIG. 18, a growth suppression film 7 may be formed on the growth suppression region DA.

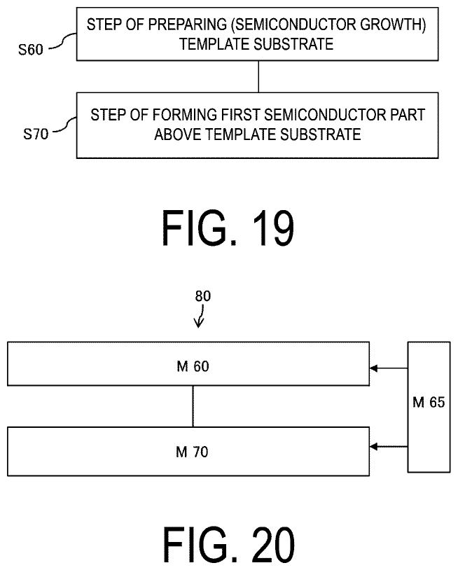

FIG. 19 is a flowchart illustrating a method for manufacturing a semiconductor substrate according to the present embodiment. As illustrated in FIG. 19, the method for manufacturing a semiconductor substrate according to the present embodiment includes step S60 of preparing the semiconductor growth template substrate, and step S70 of forming the first semiconductor part located above the template substrate. FIG. 20 is a block diagram illustrating the manufacturing apparatus for a semiconductor substrate according to the present embodiment. A manufacturing apparatus 80 of a semiconductor substrate includes an apparatus M60 that performs the step S60 in FIG. 19, an apparatus M70 that performs the step S70 in FIG. 20, and a control device M65 that controls the apparatus M60 and the apparatus M70.

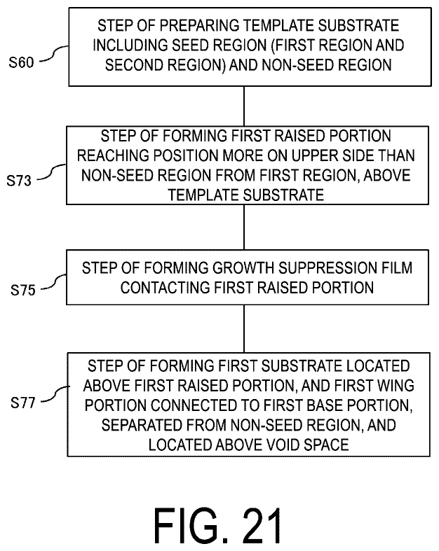

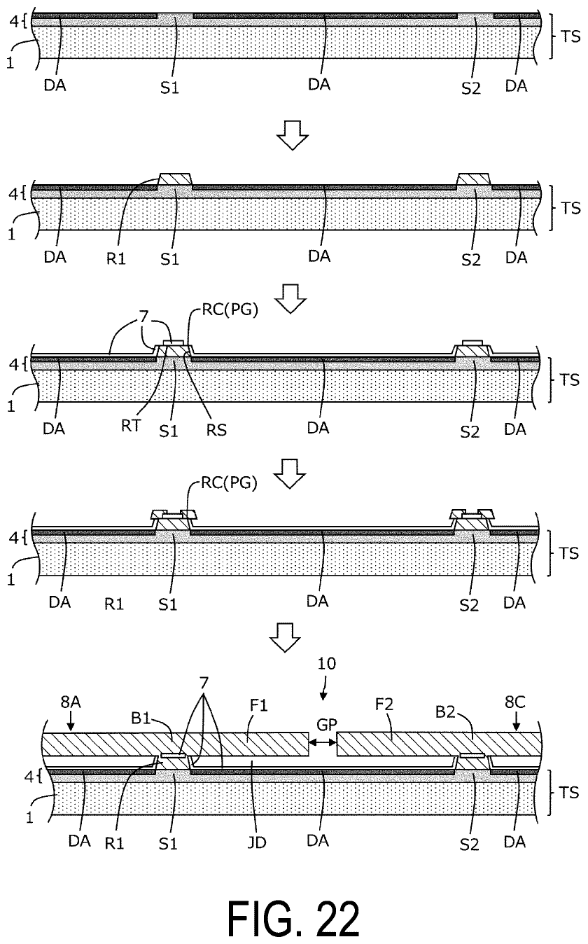

FIG. 21 is a flowchart illustrating a method for manufacturing a semiconductor substrate according to the present embodiment. FIG. 22 is cross-sectional views each illustrating the manufacturing method for a semiconductor substrate according to the present embodiment. As illustrated in FIGS. 21 and 22, the method for manufacturing a semiconductor substrate according to the present embodiment includes step S60 of preparing the template substrate TS including the seed region (the first and the second regions S1 and S2) and the growth suppression region DA, step S73 of forming the first raised portion R1 reaching a position more on the upper side than the growth suppression region DA from the first region S1, above the template substrate TS, step S75 of forming the growth suppression film 7 in contact with the first raised portion R1, and step S77 of forming the first base portion B1 located above the first raised portion R1 and the first wing portion F1 connected to the first base portion B1 and located above the void space JD while being separated from the growth suppression region DA.

The first base portion B1 and the first wing portion F1 may be formed by using, as the growth starting point PG, the corner portion RC where the upper surface RT and the side surface RS of the first raised portion R1 intersect as illustrated in FIG. 22. As described above, the corner portion RC may be used as a growth starting point PG. However, the configuration is not limited thereto. A defect portion (for example, a small opening) may be formed in the growth suppression film 7 on the first raised portion R1, and the defect portion of the growth suppression film 7 may be used as a growth starting point of the first base portion B1 and the first wing portion F1.

The first raised portion R1, the growth suppression film 7, the first base portion B1, and the first wing portion F1 may be continuously formed by using a metal organic chemical vapor deposition (MOCVD) device. The first raised portion R1 includes a GaN-based semiconductor. The growth suppression film 7 contains silicon nitride. The first raised portion R1 may be formed by supplying a raw material serving as a gallium source (organic materials such as trimethylgallium (TMG) and triethylgallium (TEG)) and a raw material serving as a nitrogen source (ammonia gas (NH₃)). The growth suppression film 7 may be formed by stopping the supply of the raw material serving as the gallium source and supplying a silicon-based material (for example, SiH₄), while maintaining the supply of the raw material serving as the nitrogen source. The first base portion B1 and the first wing portion F1 may include a GaN-based semiconductor. The first base portion B1 and the first wing portion F1 may be formed by stopping the supply of the silicon-based material and supplying the raw material serving as a gallium source, while maintaining the supply of the raw material serving as a nitrogen source. A small amount of the silicon-based material may be continuously supplied at the doping level.

By forming the growth suppression film 7 as described above, film formation can be continuously performed, while forming a void space DJ under the wing portion F, without removing the product from the MOCVD device, and the manufacturing time and the manufacturing cost can be reduced. By forming the void space DJ and forming the wing portion F so as not to be in contact with the underlying layer 4 (the growth suppression region DA), the stress or the like applied to the semiconductor part 8 from the main substrate 1 and the underlying layer 4 can be effectively relaxed.

As in known cases, when a mask pattern is formed with a void space formed under the wing portion, the flatness of the lower surface of the wing portion (surface facing the mask portion) may be compromised. For example, when the mask layer is patterned by a lift-off method or the like to form the mask portion, burrs (protrusions) may remain at both ends of the mask portion. Due to formation over such protrusions, the flatness of the lower surface of the semiconductor layer is compromised. In the present embodiment, since the growth suppression region DA, which is an underlaying modified layer, is formed, such a protrusion is less likely to be generated, and the lower surface of the wing portion F can be easily planarized. The lower surface of the wing portion F is preferably flat because the lower surface can be used as a light extraction surface when a light emitting device is formed on the wing portion F, for example.

The growth of the first wing portion F1 and the second wing portion F2 may be stopped, before the first wing portion F1 and the second wing portion F2 growing in a direction toward the first wing portion F1 touch each other.

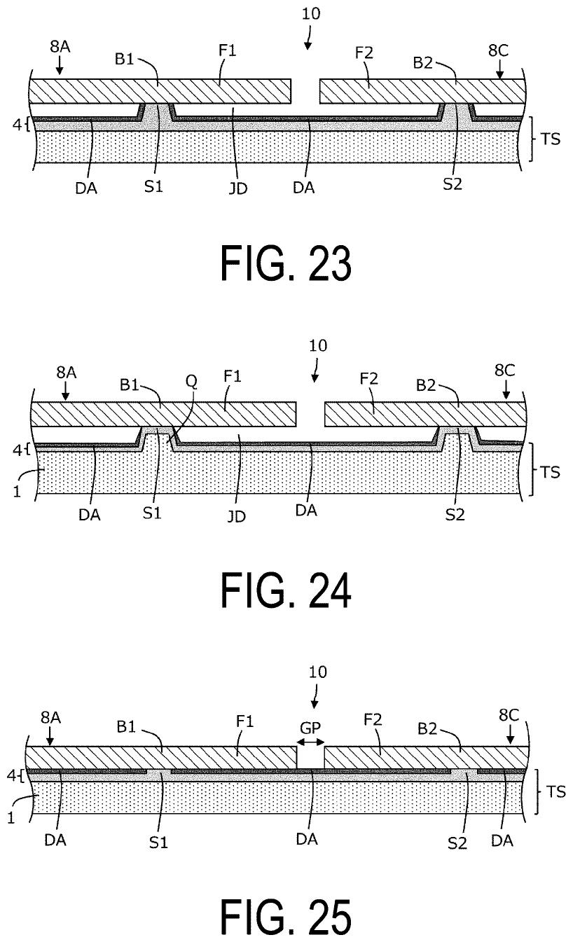

FIGS. 23 to 25 are cross-sectional views illustrating the configuration of the semiconductor substrate according to the present embodiment. In the semiconductor substrate of FIGS. 16 and 18, with the raised portion R formed, the wing portion F (F1, F2) floats from the growth suppression region DA, but this is not construed in a limiting sense. As illustrated in FIG. 23, the underlying layer 4 may be formed to make the portion including the first region S1 (the portion immediately below the first region) thicker than the portion including the growth suppression region DA (the portion immediately below the growth suppression region) in the template substrate TS. As illustrated in FIG. 24, in the template substrate TS, the main substrate 1 may have the protruding portion Q protruding upward, and the first region S1 may be formed on the protruding portion Q. As illustrated in FIG. 25, the first wing portion F1 of the first semiconductor part 8A and the second wing portion F2 of the second semiconductor part 8C may be in contact with the growth suppression region DA.

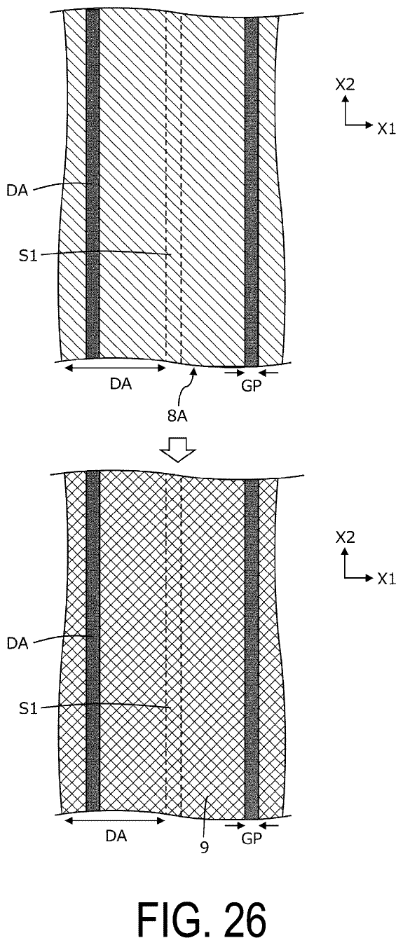

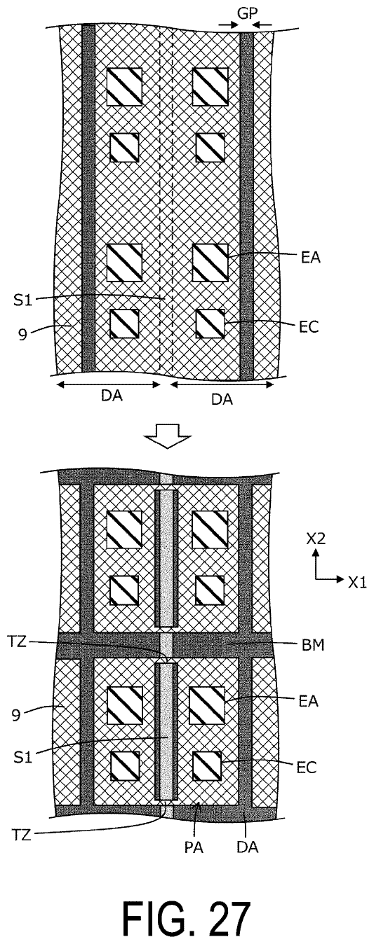

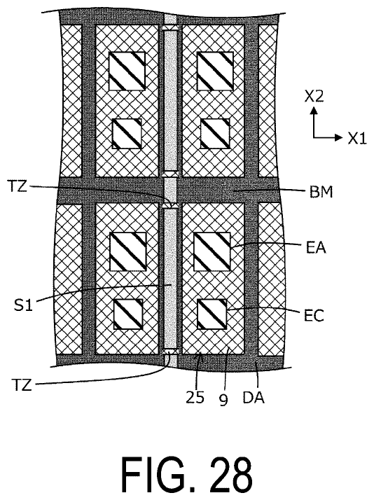

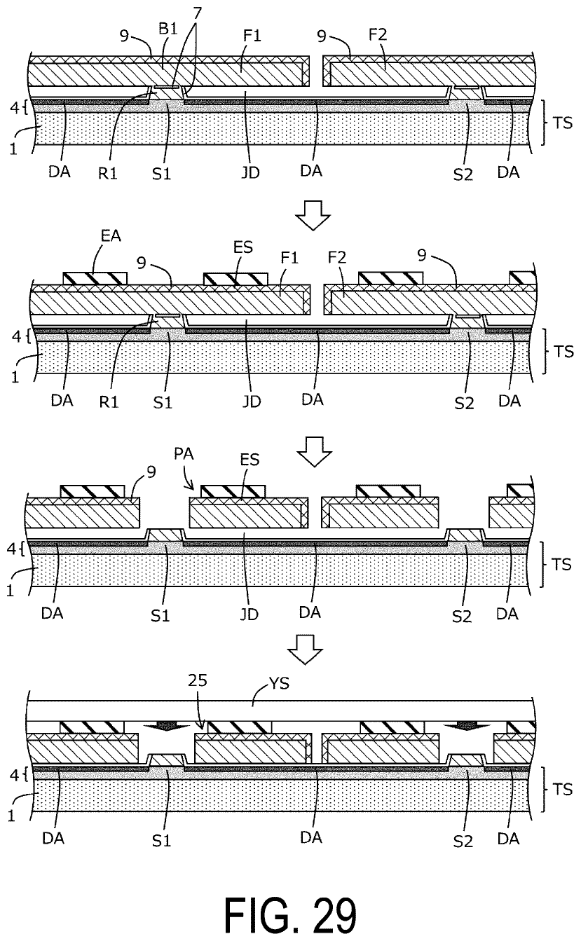

FIG. 26 is plan views each illustrating the manufacturing method for a semiconductor substrate according to the present embodiment. FIGS. 27 and 28 are plan views each illustrating the manufacturing method for a semiconductor substrate and a semiconductor device according to the present embodiment. FIG. 29 is cross-sectional views each illustrating the manufacturing method for a semiconductor substrate and a semiconductor device according to the present embodiment. As illustrated in FIGS. 26 and 29, a functional layer (device layer) 9 may be formed on the first semiconductor part 8A. For example, the functional layer 9 of a light emitting diode (LED), a laser, a photodiode (PD), a power device, or the like is formed by using MOCVD, molecular beam epitaxy (MBE), a sputtering method, or the like. The active region (for example, a light emitting region ES) of the functional layer 9 may be formed above the first wing portion F1 (device region) which is the low defect portion (low dislocation portion) (so as to overlap the first wing portion F1 in plan view).

As illustrated in FIGS. 27 and 29, electrodes EA and EC (for example, anode and cathode) are formed on the functional layer 9, and device division is implemented removing predetermined portions of the first semiconductor part 8A and the functional layer 9. Specifically, a separation groove BM parallel to the first direction X1 is formed in the first semiconductor part 8A and the functional layer 9, and an element region PA is formed by removing the first semiconductor part 8A and the functional layer 9 located on the first region S1 while leaving two tether portions TZ as a pair. The two tether portions TZ are portions, of both end portions of the element region PA facing each other in the second direction X2, connected to the first region S1.

As illustrated in FIGS. 28 and 29, the element region PA (including the wing portion F, the functional layer 9, and the electrodes EA and EC) is separated from the template substrate TS to be a semiconductor device 25. Since the void space JD is provided under the wing portion F, when a downward pressure is applied to the element region PA using a sticky or adhesive pressing body YS (an adhesive plate, an adhesive sheet, an adhesive substrate, or the like), the two tether portions TZ are easily split, and the semiconductor device 25 is separated from the template substrate TS. Specifically, the semiconductor device 25 is peeled off from the template substrate TS while being held by the pressing body YS. As described above, the void space JD effectively functions also for the element separation, and the semiconductor device 25 can be peeled off from the template substrate TS without being damaged.

Specific examples of the semiconductor device 25 include a light-emitting diode (LED), a semiconductor laser, a Schottky diode, a photodiode, transistors (including a power transistor and a high electron mobility transistor), and the like.

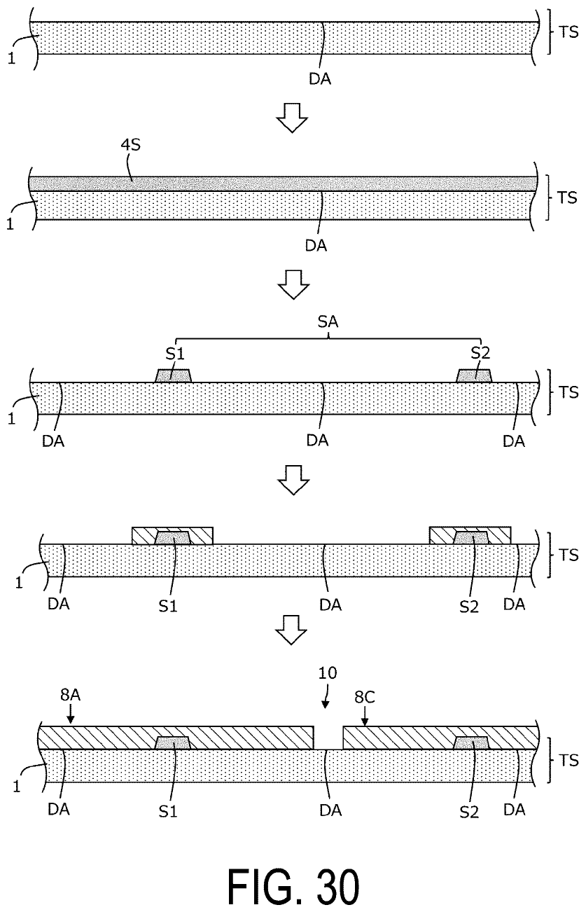

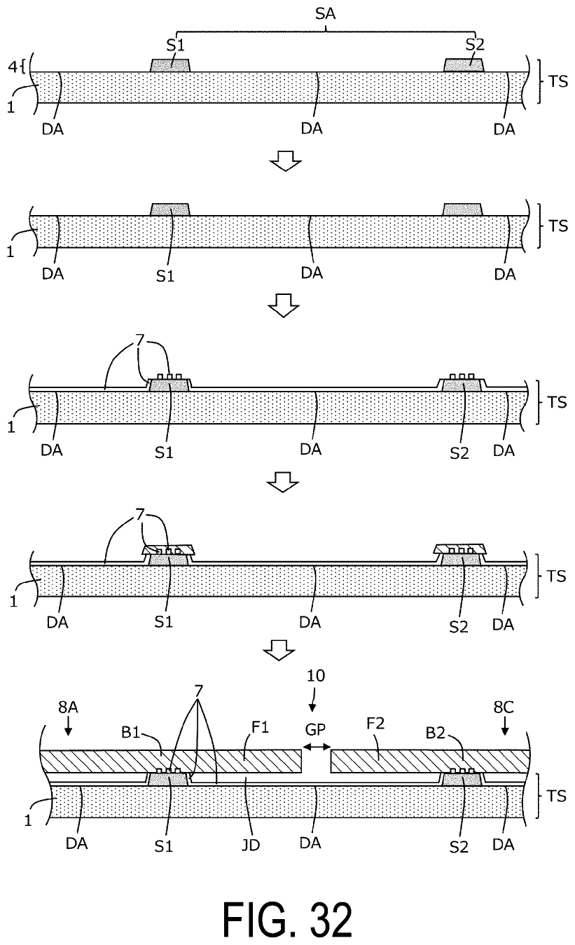

FIG. 30 is cross-sectional views each illustrating the manufacturing method for a semiconductor substrate according to the present embodiment. In the above-described embodiment, the underlying layer 4 is formed, and a predetermined region of the underlying layer 4 is modified to form the growth suppression region (non-seed region) DA, but this should not be construed in a limiting sense. As illustrated in FIG. 30, by using a non-nitride semiconductor based bulk crystal substrate (for example, a sapphire substrate) for the main substrate 1, the surface of the main substrate 1 can function as the growth suppression region (non-seed region) DA. In particular, the seed layer 4S planarly formed on the main substrate 1 is patterned by photolithography or the like to form a seed pattern SA (the first and the second regions S1 and S2), the first semiconductor part 8A is formed by ELO from the first region S1 on the growth suppression region DA (for example, the sapphire substrate surface), and the second semiconductor part 8C is formed by ELO from the second region S2 on the growth suppression region DA. The seed pattern (seed region) SA may be a nitride semiconductor such as AlN, GaN, or AlInGaN formed by using a MOCVD method, a sputtering method, or the like. A wing portion F1 of the first semiconductor part 8A may be in contact with the growth suppression region DA (bulk crystal substrate surface). Note that a growth suppression film may be formed after the seed pattern SA is formed and before the first semiconductor part 8A and the second semiconductor part 8C are formed by ELO (for example, see FIG. 32 described later). The semiconductor growth template substrate TS includes the main substrate 1 and the seed pattern SA located above the main substrate 1, the main substrate 1 is a substrate made of a bulk crystal that is not a nitride semiconductor, and part of the surface of the main substrate 1 serves as the growth suppression region (non-seed region) DA that does not overlap the seed pattern SA in plan view.

The seed pattern SA includes the first region S1 and the second region S2. In plan view, the growth suppression region (non-seed region) DA may be located between the first region S1 and the second region S2. The first region S1 and the second region S2 may be arranged in a stripe pattern. The surface of the bulk crystal may be exposed in the growth suppression region (non-seed region) DA.

The seed pattern SA may include a nitride semiconductor, and the first and the second regions S1 and S2 may be arranged in the a-axis direction of the nitride semiconductors. The material of the seed pattern SA may be an aluminum nitride. The seed pattern SA may be located more on the upper side than the growth suppression region (non-seed region) DA. The width of the growth suppression region DA (the width of the nitride semiconductor including the first region S1 in the a-axis direction) may be five times the widths of the first region S1 or more. The main substrate 1 may be a sapphire substrate or a silicon carbide substrate. The bulk crystal constituting the main substrate 1 may not include silicon (Si). When the main substrate 1 is a sapphire substrate or a silicon carbide substrate, the possibility that the GaN-based semiconductor material of the semiconductor part (8A, 8C) reacts with the main substrate 1 in the growth suppression region (non-seed region) DA is low as compared with the case where the main substrate is a silicon substrate.

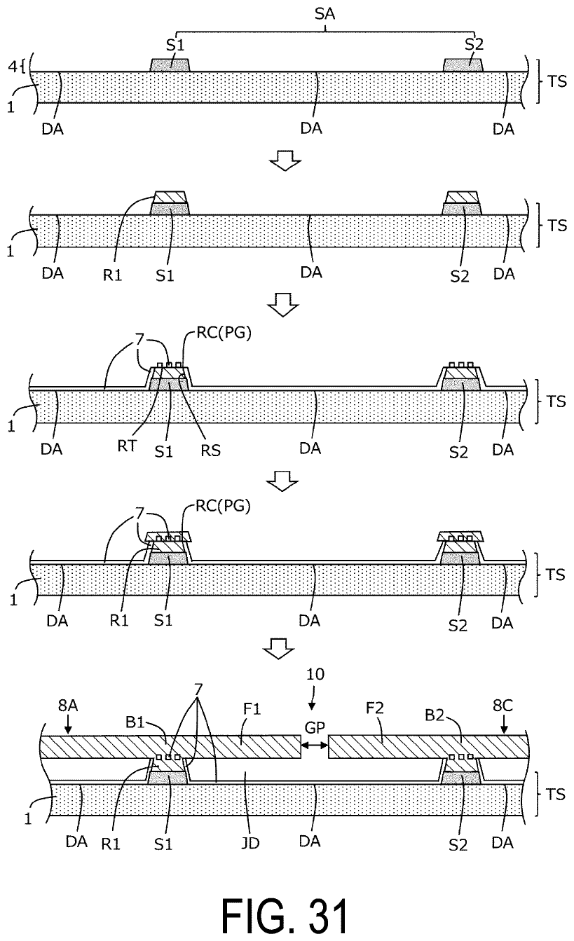

FIG. 31 is cross-sectional views each illustrating the manufacturing method for a semiconductor substrate according to the present embodiment. In FIG. 31, a step of preparing the template substrate TS including the seed pattern SA (the first and the second regions S1 and S2) and the growth suppression region DA is performed. Specifically, the seed layer 4S (nitride semiconductor) is formed on the main substrate 1 (sapphire substrate for example) made of bulk crystal and patterned. Thus, the seed pattern SA (the first and the second regions S1 and S2), and the exposed surface of the bulk crystal substrate (sapphire substrate surface for example) is used as the growth suppression region DA. Next, a step of forming the first raised portion R1 reaching a position more on the upper side than the growth suppression region DA from the first region S1, above the template substrate TS is performed. Next, a step of forming the growth suppression film 7 in contact with the first raised portion R1 is performed. Next, a step of forming the first base portion B1 located above the first raised portion R1, and the first wing portion F1 located above the void space JD, while being connected to the first base portion B1 and separated from the growth suppression region DA is performed.

The first base portion B1 and the first wing portion F1 may be formed by using, as the growth starting point PG, the corner portion RC where the upper surface RT and the side surface RS of the first raised portion R1 intersect as illustrated in FIG. 31. As described above, the corner portion RC may be used as a growth starting point PG. However, the configuration is not limited thereto. A defect portion (for example, a small opening or step break) may be formed in the growth suppression film 7 on the first raised portion R1, and the defect portion of the growth suppression film 7 may be used as a growth starting point of the first base portion B1 and the first wing portion F1.

The first raised portion R1, the growth suppression film 7, the first base portion B1, and the first wing portion F1 may be continuously formed by using a metal organic chemical vapor deposition (MOCVD) device. The first raised portion R1 includes a GaN-based semiconductor. The growth suppression film 7 contains silicon nitride. The first raised portion R1 may be formed by supplying a raw material serving as a gallium source (organic materials such as trimethylgallium (TMG) and triethylgallium (TEG)) and a raw material serving as a nitrogen source (ammonia gas (NH₃)). The growth suppression film 7 may be formed by stopping the supply of the raw material serving as the gallium source and supplying a silicon-based material (for example, SiH₄), while maintaining the supply of the raw material serving as the nitrogen source. The first base portion B1 and the first wing portion F1 may include a GaN-based semiconductor. The first base portion B1 and the first wing portion F1 may be formed by stopping the supply of the silicon-based material and supplying the raw material serving as a gallium source, while maintaining the supply of the raw material serving as a nitrogen source. A small amount of the silicon-based material may be continuously supplied at the doping level. The growth suppression film 7 may be formed on the growth suppression region DA (on the surface of a bulk crystal substrate such as a sapphire substrate).

By forming the growth suppression film 7 as described above, film formation can be continuously performed, while forming a void space DJ under the wing portion F, without removing the product from the MOCVD device, and the manufacturing time and the manufacturing cost can be reduced. In addition, with the growth suppression film 7 formed on the growth suppression region (non-seed region) DA, it is possible to reduce the possibility that the material of the GaN-based semiconductor react with the surfaces of the main substrate when the first base portion B1 and the first wing portion F1 are grown. By forming the void space DJ and forming the wing portion F (F1, F2) so as not to be in contact with the surface of the main substrate 1 that is a bulk crystal (the non-seed region DA that is a growth suppression region), the stress or the like applied to the semiconductor part 8 (8A, 8C) from the main substrate 1.

FIG. 32 is cross-sectional views each illustrating the manufacturing method for a semiconductor substrate according to the present embodiment. As illustrated in FIG. 32, the step of forming the first raised portion R1 may be omitted, and the growth suppression film 7 may be formed on the first and the second regions S1 and S2, and then the semiconductor part 8 (8A, 8C) may be grown by ELO (lateral growth).

The semiconductor substrate 10 obtained in FIGS. 30 to 32 includes the main substrate 1, the seed pattern SA located above the main substrate 1 and including the first region S1, and the first semiconductor part 8A extending from the first region S1. The main substrate 1 is a substrate made of bulk crystal that is not a nitride semiconductor. Part of the surface of the main substrate 1 may be the non-seed region (growth suppression region) DA not overlapping the seed pattern SA in plan view. The first semiconductor part 8A may extend from the first region S1 to above each of the non-seed regions (growth suppression regions) DA located on both sides of the first region S1.

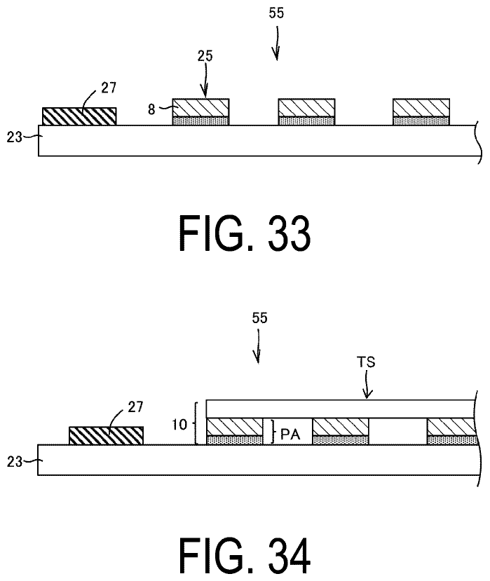

FIG. 33 is a schematic view illustrating a configuration of an electronic device according to the present embodiment. An electronic device 55 in FIG. 33 includes the semiconductor device 25 including the semiconductor part 8, a drive substrate 23 with the semiconductor device 25 mounted, and a control circuit 27 that controls the drive substrate 23. FIG. 34 is a schematic view illustrating another configuration of the electronic device according to the present embodiment. The element region (element portion) PA may not be peeled off from the template substrate TS. The electronic device 55 in FIG. 34 includes the semiconductor substrate 10 including the template substrate TS and the element region PA, the drive substrate 23 with the semiconductor substrate 10 mounted, and the control circuit 27 that controls the drive substrate 23. In this case, the main substrate included in the template substrate TS may be a light-transmissive substrate (for example, a sapphire substrate). Examples of the electronic device 55 include a light emitting device, a display device, a laser emitting device (including a Fabry-Perot type and a surface emitting type), a measurement device, an illumination device, a communication apparatus, an information processing apparatus, and a power control device.

### Supplementary Note

The foregoing disclosure has been presented for purposes of illustration and description, and not limitation. Many variations will be apparent to those skilled in the art based on these illustrations and descriptions, and these variations are included in the embodiments.

### REFERENCE SIGNS

1 Main substrate
4 Underlying layer
7 Growth suppression film
8A First semiconductor part
8C Second semiconductor part
10 Semiconductor substrate
25 Semiconductor device
30 Manufacturing apparatus for template Substrate
55 Electronic device
R1 First raised portion
R2 Second raised portion
B1 First base portion
B2 Second base portion
F1 First wing portion
F2 Second wing portion
JD Void space
SA Seed region (seed pattern)
S1 First region
S2 Second region
DA Growth suppression region (non-seed region)
TS Template substrate (semiconductor growth template substrate)

1.-21 (canceled)

22. A method for manufacturing a semiconductor substrate, comprising:
preparing a semiconductor substrate including:
a main substrate,
an underlying layer, which is located above the main substrate and contains a nitride semiconductor as a main constituent,
wherein the underlying layer comprises a seed region and a growth region, an argon concentration of the growth suppression region is higher than an argon concentration of the seed region; and
forming a semiconductor part from the seed region, the semiconductor part contains a nitride semiconductor.

23. A method for manufacturing a semiconductor substrate according to claim 22, wherein
the forming is performed by an Epitaxial Lateral Overgrowth method.

24. A semiconductor substrate comprising:
a main substrate;
an underlying layer, which is located above the main substrate and contains a nitride semiconductor as a main constituent;
a semiconductor part located in the underlying layer and containing a nitride semiconductor, wherein
the underlying layer comprises a seed region and a growth region, an argon concentration of the growth suppression region is higher than an argon concentration of the seed region, and
the semiconductor part comprises a base portion elongated upward from the seed region and a wing portion elongated from the base portion over the growth suppression region.

25. A semiconductor substrate according to claim 24, wherein
the underlying layer contains aluminum nitride as a main constituent.

26. A semiconductor substrate according to claim 24, wherein
the underlying layer contains a metal element which is not contained in the semiconductor part.

27. A semiconductor substrate according to claim 24, wherein
the seed region and the growth suppression region are arranged in a-axis direction of the nitride semiconductor contained in the semiconductor part.

28. A semiconductor substrate according to claim 24, wherein
the growth suppression region includes an oxide of the nitride semiconductor contained in the underlying layer.

29. A semiconductor substrate according to claim 24, wherein
a thickness of the growth suppression region is 100 nm or less.

30. A semiconductor substrate according to claim 24, wherein
an argon concentration of the growth suppression region is 2×1018/cm3 or more.

31. A semiconductor substrate according to claim 24, wherein
a threading dislocation of the wing portion is lower than a threading dislocation of the base portion.

32. A semiconductor substrate according to claim 24, wherein
the wing portion is not in contact with the growth suppression region.

33. A semiconductor substrate according to claim 24, wherein
the wing portion is in contact with the growth suppression region.

34. A semiconductor substrate according to claim 24, wherein
in the a-axis direction of the nitride semiconductor contained in the semiconductor part, a length of the growth suppression region is five times or more as long as a length of the seed region.

35. A semiconductor substrate according to claim 24, wherein
the main substrate is a heterogeneous substrate having a lattice constant different from that of the nitride semiconductor contained in the semiconductor part.
